(19) United States
(12) Patent Application Publication
(10) Pub. No.: US 2018/0223416 A1
(43) Pub. Date: Aug. 9, 2018

(54) ALUMINUM SPUTTERING TARGET

(71) Applicant: KOBELCO RESEARCH INSTITUTE, INC., Kobe-shi (JP)

(72) Inventor: Hiromi MATSUMURA, Takasago-shi (JP)

(73) Assignee: KOBELCO RESEARCH INSTITUTE, INC., Kobe-shi (JP)

(21) Appl. No.: 15/749,937

(22) PCT Filed: Jun. 3, 2016
(86) PCT No.: PCT/JP2016/066663

§ 371 Date: Feb. 2, 2018

(30) Foreign Application Priority Data
Aug. 3, 2015 (JP) 2015-153554

(51) Int. Cl. C23C 14/34; H01L 21/285

(52) U.S. Cl. CPC C23C 14/3407; C22C 21/00; H01L 21/285

(57) ABSTRACT

Provided is a sputtering target that can reduce the occurrence of flaws while having the same level of conductivity as a conventional aluminum sputtering target. The aluminum sputtering target contains 0.005 atomic % to 0.04 atomic % of Ni; and 0.005 atomic % to 0.06 atomic % of La, with the balance being Al and inevitable impurities.

### TECHNICAL FIELD

The present invention relates to an aluminum sputtering target used for forming electrodes of a thin film transistor for display devices, such as a liquid crystal display and a Micro Electro Mechanical System (MEMS) display, and the like.

### BACKGROUND ART

Aluminum thin films have been used as scanning electrodes and signal electrodes of display devices, such as liquid crystal displays, because they have low electric resistance and are easy to process by etching. The aluminum thin films are generally formed by a sputtering method using a sputtering target.

A vacuum vapor deposition method is known as a main film formation method of a metal thin film, other than the sputtering method. The sputtering method has an advantage that it can form a thin film with the same composition as the sputtering target, as compared to a method such as the vacuum vapor deposition method. The sputtering method is a superior film formation method in terms of industry because it enables stable film formation over a large area.

Aluminum sputtering targets used for the sputtering method are known, for example, as mentioned in Patent Documents 1 and 2. Patent Document 1 discloses an Al-based target material used in electrodes of a liquid crystal display and a method for manufacturing an Al-based target material. The target material disclosed in Patent Document 1 has a Vickers hardness (Hv) of 25 or less, thereby making it possible to suppress a phenomenon called a splash, specifically, a phenomenon in which a part of the target material is overheated due to the lack of cooling, caused by defects in the target material, to become a liquid phase and then adheres to a substrate.

In Patent Document 2, after the hardness of a sputtering surface side of the Al-based sputtering target material is adjusted to Hv20 or more, finishing machining is performed on the sputtering surface side. This can suppress the formation of protrusions, called nodules, at the surface of the target material due to frequent occurrence of abnormal discharge just after the start of sputtering to prevent such the protrusions from acting as a starting point of the abnormal discharge.

### PRIOR ART DOCUMENT

### Patent Document

Patent Document 1: JP H09-235666 A

Patent Document 2: JP 2001-279433 A

### SUMMARY OF THE INVENTION

### Problems to be Solved by the Invention

In response to an increase in size of substrates used in liquid crystal displays, aluminum sputtering targets have been increased in size. Among them, a large-sized aluminum sputtering target having width and length of 2.5 m or more is also used. The conventional aluminum sputtering targets, including those disclosed in Patent Documents 1 and 2, have problems that they have low strength as the material and are more likely to have a flaw on a surface thereof, because they hardly contain any element other than Al and the crystal structure thereof is a face centered cubic structure.

For example, the contact with the aluminum sputtering target during delivery in a process occasionally causes a flaw on the surface of the sputtering target. The probability of occurrence of such a flaw tends to increase as the size of the aluminum sputtering target becomes larger.

If the aluminum sputtering target with such a flaw is used to deposit a film on a substrate, the inconvenience, such as the formation of splashes, will occur from a flawed part as a starting point. For this reason, when the sputtering target is mounted on a sputtering apparatus to deposit the film, normally, after performing film formation onto a dummy substrate, called pre-sputtering, the film formation onto a target substrate is performed. The presputtering is a method for decreasing flaws on the surface of the sputtering target, thereby reducing the occurrence of splashes when sputtering is performed onto a target substrate.

As mentioned above, since the surface of the aluminum sputtering target is more likely to have a flaw, the presputtering cannot be disadvantageously omitted.

The present invention has been made to solve the foregoing problems, and it is an object of the present invention to provide a sputtering target that can reduce the occurrence of flaws while having the same level of conductivity as a conventional aluminum sputtering target.

### Means for Solving the Problems

An aluminum sputtering target of the present invention, which can solve the above-mentioned problems, contains: 0.005 atomic % to 0.04 atomic % of Ni; and 0.005 atomic % to 0.06 atomic % of La, with the balance being Al and inevitable impurities.

In a preferred embodiment of the present invention, a Vickers hardness is 25 or more.

In a preferred embodiment of the present invention, the aluminum sputtering target contains: 0.01 atomic % to 0.03 atomic % of Ni; and 0.03 atomic % to 0.05 atomic % of La.

### Effects of the Invention

Accordingly, the present invention can provide an aluminum sputtering target that reduces the occurrence of flaws while having the same level of conductivity as the conventional aluminum sputtering target.

### Mode for Carrying Out the Invention

The following embodiments are only to exemplify an aluminum sputtering target that embodies the technical idea of the present invention, and the present invention is not limited to the following embodiments.

The inventors of the present application have intensively studied and found that by adding a small amount of Ni which is solid-soluted or which could slightly precipitate an Al—Ni-based intermetallic compound as well as a small amount of La which is solid-soluted or which could slightly precipitate an Al—La-based intermetallic compound, in more detail, by adding 0.005 atomic % to 0.04 atomic % of Ni as well as 0.005 atomic % to 0.06 atomic % of La with the balance being Al and inevitable impurities, an obtained aluminum sputtering target can reduce the occurrence of flaws at its surface, while having the same level of conductivity as the conventional aluminum sputtering target, as mentioned in detail below. Thus, the present invention has been completed.

An Al—Ni—La alloy sputtering target (aluminum alloy sputtering target) disclosed in, for example, JP 2008-127624 A is known as a sputtering target containing Al as a main component with Ni and La added. The Al—Ni—La alloy sputtering target disclosed in JP 2008-127624 A is designed to add Ni and La to an Al with the aim of omitting a bimetal layer made of high-melting-point metals, such as Mo, Cr, Ti or W, formed on a sputtered layer on the substrate. Furthermore, in the Al—Ni—La alloy sputtering target mentioned in this JP 2008-127624 A, in order to suppress the occurrence of splashes, regarding each of an Al—Ni-based intermetallic compound and an Al—La-based intermetallic compound, the ranges of area ratios occupied by intermetallic compounds having grain size within a predetermined range is defined. Specifically, it is disclosed that a Ni content is set at 0.05 atomic % to 5 atomic %, and a La content is set at 0.10 atomic % to 1 atomic %.

That is, in the conventional Al—Ni—La alloy sputtering targets, including one disclosed in JP 2008-127624 A, relatively large amounts of Ni and La are added to positively form an Al—Ni-based intermetallic compound and an Al—La-based intermetallic compound. In addition, in the Al—Ni—La alloy sputtering target disclosed in this JP 2008-127624 A, the area ratio of each of the intermetallic compounds having the grain size within the predetermined range is specified as mentioned above, thereby suppressing splashes that occur due to the dropping of intermetallic compounds with small grain size and due to the high area ratio of intermetallic compounds with large grain size.

Such an Al—Ni—La alloy sputtering target has a higher electric resistance than an aluminum sputtering target and hence its applications are limited. In addition, due to relatively large amounts of Ni and La, it is difficult to use a simple method, such as vacuum melting, in order to homogenize the entire composition of the sputtering target. Thus, the use of a special method, such as spray forming, is normally required. Consequently, this kind of Al—Ni—La alloy sputtering target has low productivity, compared to the aluminum sputtering target which can be manufactured by vacuum melting.

In contrast, an aluminum sputtering target according to the present invention contains: 0.005 atomic % to 0.04 atomic % of Ni; and 0.005 atomic % to 0.06 atomic % of La. The balance of the aluminum sputtering target is composed of Al and inevitable impurities. That is, in the conventional Al—Ni—La alloy sputtering targets, the composition ranges of Ni and La are not considered because it is regarded that the composition cannot obtain sufficient amounts of an Al—Ni-based intermetallic compound and an Al—La-based intermetallic compound.

The term “aluminum sputtering target” as used herein is a concept that encompasses not only a sputtering target composed of aluminum and inevitable impurities, but also a sputtering target that further contains a relatively small amount, e.g., approximately 0.1 mass % or less in total, of additive elements. The term “aluminum thin film” as used herein is a concept that encompasses not only a thin film composed of aluminum and inevitable impurities, but also a sputtered thin film that further contains a relatively small amount, e.g., approximately 0.1 mass % or less in total, of additive elements.

The aluminum sputtering target according to the present invention will be described in detail below.

The aluminum sputtering target according to the present invention contains: 0.005 atomic % to 0.04 atomic % of Ni; and 0.005 atomic % to 0.06 atomic % of La, with the balance being Al and inevitable impurities. First, this composition will be described in detail.

### 1. Composition

### (1) Nickel (Ni)

The Ni content is in a range of 0.005 atomic % to 0.04 atomic %. The solid-solubility limit of Ni relative to Al, which varies depending on the literature, is in a range of approximately 0.01 atomic % to approximately 0.04 atomic %. That is, the whole amount of Ni contained in the sputtering material is solid-soluted in Al, or otherwise a small amount of Ni in the whole Ni is segregated as an Al—Ni-based intermetallic compound at grain boundaries in an aluminum crystal microstructure, with the remaining Ni being solid-soluted in Al. With this configuration, the aluminum sputtering target according to the present invention can improve the material strength while having the same high level of conductivity as the conventional aluminum sputtering target. When an intermetallic compound of Ni is precipitated, the segregation of Ni at grain boundaries is due to the fact that the atomic radius of Ni is considerably smaller than the atomic radius of Al.

Such improvement of the material strength is achieved along with the improvement of the hardness. Thus, the aluminum sputtering target subjected to machining, such as cutting, is less likely to have flaws on its surface. Consequently, splashes that occur at an initial stage of sputtering can be reduced.

The Ni content is preferably in a range of 0.01 atomic % to 0.03 atomic %, because the above-mentioned effects can be obtained more reliably. If the Ni content is less than 0.005 atomic %, an increase in the material strength is not sufficient. Meanwhile, if the Ni content exceeds 0.04 atomic %, the conductivity is reduced.

“the same level of conductivity as the conventional aluminum sputtering target” as used herein means, for example, a case in which the thin-film resistivity of an aluminum thin film formed on a substrate by sputtering method using the aluminum sputtering target is 1.05 times or less the thin-film resistivity of an aluminum thin film formed on a substrate by the same sputtering method using a pure aluminum sputtering target.

As shown in Examples mentioned later, in some cases, the thin-film resistivity of an aluminum thin film formed using the aluminum sputtering target according to the present invention is less than one time the thin-film resistivity of an aluminum thin film formed on a substrate by the same sputtering method using a pure aluminum sputtering target. That is, in some cases, the conductivity of the aluminum thin film formed using the aluminum sputtering target according to the present invention is more excellent than the conductivity of an aluminum thin film formed using a pure aluminum sputtering target. The reason for this is supposed to be as follows, but this is not intended to limit the technical scope of the present invention. As shown in Examples mentioned later, in the measurement of the thin-film resistivity, Mo thin films are laminated as upper and lower layers on the aluminum thin film, followed by heating, for example, at 450° C., and then the resistivity of the aluminum thin film is measured. The aluminum thin film formed using the aluminum sputtering target according to the present invention has Ni added thereto and thus has a larger grain size than a pure aluminum thin film. The pure aluminum thin film having a smaller grain size and thus a large amount of grain boundaries has a high electric resistance in some cases.

### (2) Lanthanum (La)

The La content is in a range of 0.005 atomic % to 0.06 atomic %. The solid-solubility limit of La relative to Al, which varies depending on the literature, is approximately 0.01 atomic %. That is, the whole amount of La contained in the sputtering material is solid-soluted in Al, or otherwise part of the whole La is precipitated as an Al—La-based intermetallic compound within grains of an aluminum crystal microstructure, with most of the remaining La being solid-soluted as substituted atoms in Al. The presence of La as the substituted atoms causes the accumulation of dislocation to increase the material strength during rolling as mentioned later. Furthermore, part of the whole La is segregated at grain boundaries of a natural oxide film of Al on the surface, which contributes to improving the strength of an oxide film.

With this configuration, the aluminum sputtering target according to the present invention can improve the material strength while having the same high level of conductivity as the conventional aluminum sputtering target. When La is precipitated as an intermetallic compound, the precipitation of La in grains is due to the fact that the atomic radius of La is considerably larger than the atomic radius of Al.

Such improvement of the material strength is achieved along with the improvement of the hardness. Thus, the aluminum sputtering target subjected to machining, such as cutting, is less likely to have flaws on its surface. Consequently, splashes that would otherwise occur at an initial stage of sputtering can be reduced.

The La content is preferably in a range of 0.03 atomic % to 0.05 atomic %. The La content is set at 0.03 atomic % or more, thereby the sufficient material strength can be obtained more reliably. Meanwhile, if the La content exceeds 0.05 atomic %, the precipitation amount of the hard Al—La-based intermetallic compound is increased, and during cutting, the frequency of occurrence of fine scratches from the intermetallic compound as a starting point tends to increase. If the La content is less than 0.005 atomic %, an increase in the material strength is not sufficient. Meanwhile, if the La content exceeds 0.06 atomic %, the conductivity is reduced.

As mentioned above, Ni is precipitated at the grain boundaries, which contributes to increasing the strength. Meanwhile, La forms a substitutional solid solution in grains, contributing to increasing the strength, and is segregated at grain boundaries in an Al oxide film on the surface, which also contributes to improving the strength. It is found that since Ni and La contribute to improving the strength with different mechanisms in this way, a combination of Ni and La is the optimal one that can exhibit the effect of improving the material strength due to the summation of their respective effects.

That is, the aluminum sputtering target according to the present invention contains both Ni and La within the above-mentioned composition ranges, thereby the high material strength can be obtained reliably and high hardness also can be obtained, while the same high level of conductivity as the conventional aluminum sputtering target is secured. With this configuration, flaws that occur at the surface of the aluminum sputtering target subjected to the machining can be reduced sufficiently. This enables the reduction of splashes that occur at an initial stage of sputtering. Consequently, the number of dummy substrates used for presputtering can be surely decreased.

### (3) Balance

The balance is Al and inevitable impurities. In a preferred embodiment, the total content of the inevitable impurities is 0.01 mass % or less. The content of the inevitable impurities is normally managed in terms of mass ratio in many cases and thus is represented in units of mass %. Examples of the inevitable impurities can contain Fe, Si and Cu.

### 2. Hardness

In the aluminum sputtering target, its surface part preferably has a Vickers hardness of 25 or more. This is because the high hardness can surely reduce the occurrence of flaws. The Vickers hardness of 25 or more can be achieved, for example, by setting the temperature of a heat treatment after rolling at 300° C. or lower, or by performing cold rolling as the rolling at a reduction rate of 80% or more.

### 3. Form of Aluminum Sputtering Target

The aluminum sputtering target according to the present invention may have an arbitrary shape that can be taken by known aluminum sputtering targets. These kinds of shapes can include a square, a rectangle, a circle, an ellipse, and a shape forming a part of these shapes, in the top view. The aluminum sputtering target with such a shape may have an arbitrary size. The size of the aluminum sputtering target according to the present invention can be, for example, the length of 100 mm to 4,000 mm, the width of 100 mm to 3,000 mm, and the thickness of 5 mm to 35 mm.

The aluminum sputtering target according to the present invention may have arbitrary surface properties that are exhibited by known aluminum sputtering targets. For example, a surface with which ions collide may be a mechanically finished surface subjected to cutting or the like. The surface with which ions collides is preferably a polished surface. The polished surface can surely reduce the occurrence of splashes.

For example, the aluminum sputtering target according to the present invention may be used in the following way to form an aluminum thin film on a substrate by sputtering. The aluminum sputtering target according to the present invention is bonded to a backing plate made of, for example, copper or a copper alloy, by using a brazing filler metal. The sputtering target is mounted on a sputtering apparatus as a vacuum device while being bonded to the backing plate in this way.

### 4. Manufacturing Method

The aluminum sputtering target according to the present invention may be manufactured by using an arbitrary known method for manufacturing an aluminum sputtering target. For example, the method for manufacturing an aluminum sputtering target according to the present invention will be described below.

### (1) Melt-Casting

First, a blended raw material having a predetermined composition is prepared to be melted. The raw materials constituting the blended raw material may be metal simple substances such as Al, Ni and La, or an aluminum alloy containing at least one of Ni and La. In the case of using the metal simple substitute as the raw material, each of an Al raw material and a Ni raw material preferably has a purity of 99.9 mass % or more, and more preferably 99.95 mass % or more. A La raw material preferably has a purity of 99 mass % or more, and more preferably 99.5 mass % or more. After melting the blended raw material by vacuum melting, casting is performed to obtain an ingot with a predetermined composition.

The aluminum sputtering target according to the present invention has an advantage that its composition can be homogenized without using spray forming, i.e., even by vacuum melting, because the Ni content and La content therein are smaller than those in the conventional Al—Ni—La sputtering target. However, this does not mean that the melt-casting using spray forming is excluded, and, an ingot may be obtained by spray forming.

Furthermore, instead of the vacuum melting, the melting may be performed in an inert atmosphere such as an argon atmosphere.

The inventors have confirmed that since Ni and La have high vapor pressure and their evaporation is limited during melting, the blended raw material composition, the composition of the ingot obtained by the melt-casting, and the composition of the aluminum sputtering target finally obtained are substantially the same. For this reason, the blended composition during melting may be regarded as the composition of the obtained aluminum sputtering target. It is preferable to confirm the composition of the aluminum sputtering target actually obtained.

### (2) Rolling, Heat Treatment, Machining

The obtained ingot is rolled to have substantially the same thickness as the aluminum sputtering target, which is intended to be obtained, thereby a rolled material (plate material) is obtained. The rolling may be, for example, cold rolling. Heat treatment (annealing) is applied to the obtained rolled material. For example, a heat treatment temperature may be in a range of 240° C. to 260° C., a holding time may be in a range of 2 hours to 3 hours, and an atmosphere may be air.

The rolled material after the heat treatment is subjected to machining, thus an aluminum sputtering target is obtained. For example, machining can include cutting using a lathe or the like and punching. After the machining, polishing may be further performed to smooth the surface, especially, the surface with which ions will collide.

### EXAMPLES

### Example 1

An Al raw material, a Ni raw material and a La raw material were blended such that a Ni added content was 0.02 atomic % and a La added content was 0.02 atomic % with the balance being Al (containing inevitable impurities), a blended raw material (raw material to be melted) was obtained. The Al raw material and Ni raw material both of which had a purity of 99.98 mass % and the La raw material which had a purity of 99.5 mass % were used. This blended raw material was subjected to vacuum melting and casting to produce an aluminum alloy ingot that had the same composition as the blended raw material.

The obtained ingot was cold-rolled, thus a rolled material was obtained. The cold rolling was performed such that its thickness before the rolling was 100 mm, while its thickness after the rolling was 8 mm, i.e., at a rolling reduction of 92%. The rolled material was subjected to heat treatment in the atmosphere at 250° C. for two hours. After cutting, the rolled material was processed by cutting as machining into an aluminum sputtering target with a shape of φ304.8 mm×5 mmt. The composition of the obtained aluminum sputtering target was confirmed to be the same as the composition of the blended raw material. The obtained aluminum sputtering target was bonded to a backing plate made of pure Cu by using the above-mentioned brazing filler metal.

### Example 2

An aluminum sputtering target was produced by the same method as in Example 1, except that the composition of a blended raw material was set to have a Ni content of 0.02 atomic % and a La content of 0.04 atomic % with the balance being Al (including inevitable impurities). The composition of the obtained aluminum sputtering target was confirmed to be the same as the composition of the blended raw material.

### Example 3

An aluminum sputtering target was produced by the same method as in Example 1, except that the composition of a blended raw material is set to have a Ni content of 0.02 atomic % and a La content of 0.06 atomic % with the balance being Al (including inevitable impurities). The composition of the obtained aluminum sputtering target was confirmed to be the same as the composition of the blended raw material.

### Comparative Example 1

An aluminum sputtering target was produced by the same method as in Example 1, except that the blended raw material was only Al raw material.

### Example 4

The aluminum sputtering target of Example 1 was further polished with a sand paper #600 to produce an aluminum sputtering target of Example 4. The obtained aluminum sputtering target was bonded to a backing plate made of pure Cu by using the brazing filler metal.

### Example 5

The aluminum sputtering target of Example 2 was further polished with a sand paper #600 to produce an aluminum sputtering target of Example 5. The obtained aluminum sputtering target was bonded to a backing plate made of pure Cu by using the brazing filler metal.

### Example 6

The aluminum sputtering target of Example 3 was further polished with a sand paper #600 to produce an aluminum sputtering target of Example 6. The obtained aluminum sputtering target was bonded to a backing plate made of pure Cu by using the brazing filler metal.

### Comparative Example 2

The aluminum sputtering target of Comparative Example 1 was further polished with a sand paper #600 to produce an aluminum sputtering target of Comparative Example 2. The obtained aluminum sputtering target was bonded to a backing plate made of pure Cu by using the brazing filler metal.

In each of Examples 1 to 6 and Comparative Examples 1 and 2, the backing plate with the aluminum sputtering target bonded thereto was mounted on a magnetron DC sputtering apparatus, and sputtering was performed at a DC power of 4.5 kW and a pressure of 0.3 Pa. Film formation was performed by the sputtering on a four-inch silicon substrate for 50 seconds per once to form an aluminum thin film of 200 nm in thickness. The silicon substrate was replaced per once of film formation, and then the sputtering was continuously performed.

The film formed on the silicon substrate was examined by an optical particle counter, and the positions of occurrence of particles were observed with a microscope. The particles were observed, and the number of occurrence of splashes was examined based on the observed shape of the particle. Table 1 shows the number of substrates on which a film was formed until the number of occurrence of splashes in each target becomes one or less per substrate. This corresponds to the number of dummy substrates required for presputtering.

As can be seen from Table 1, evaluation on each sample was conducted four times.

A Vickers hardness of the surface of the aluminum sputtering target in each of Examples 1 to 6 and Comparative Examples 1 and 2 was measured by a Vickers hardness test. The Vickers hardness test used a method which involved pressing a pyramidal diamond indenter into a sample at a load of 1 kgf and the hardness of the sample was calculated from the lengths of diagonals of a quadrilateral impression formed on the sample surface, by using a testing machine (AVK type/H-90OS23) manufactured by Akashi Seisakusho Co. Data on each target surface of the samples was acquired three times (n=3) to average the data. The obtained Vickers hardnesses of the respective samples are shown in Table 1.

TABLE 1

| | | | | Number of film-formed | | | | | |
|---|---|---|---|---|---|---|---|---|---|
| | | | | substrates until the | | | | | |
| | Sputtering | Surface | Vickers | number of splashes | | | | | Thin-film |
| | target | finishing | hardness | becomes one or less | | | | | resistivity |
| | composition | method | Hv | 1 | 2 | 3 | 4 | Average | (μΩcm) |
| Example 1 | Al—0.02Ni—0.02La | Cutting | 26.0 | 14 | 18 | 12 | 10 | 13.5 | 3.08 |
| Example 2 | Al—0.02Ni—0.04La | Cutting | 28.2 | 9 | 13 | 14 | 8 | 11.0 | 3.03 |
| Example 3 | Al—0.02Ni—0.06La | Cutting | 30.1 | 13 | 17 | 18 | 15 | 15.8 | 3.11 |
| Comparative | Pure aluminum | Cutting | 22.6 | 23 | 17 | 24 | 27 | 22.8 | 3.12 |
| Example 1 | | | | | | | | | |
| Example 4 | Al—0.02Ni—0.02La | Polishing | 25.5 | 9 | 8 | 12 | 11 | 10.0 | 3.02 |
| Example 5 | Al—0.02Ni—0.04La | Polishing | 27.5 | 7 | 8 | 6 | 8 | 7.3 | 3.00 |
| Example 6 | Al—0.02Ni—0.06La | Polishing | 29.7 | 9 | 7 | 9 | 10 | 8.8 | 3.01 |
| Comparative | Pure aluminum | Polishing | 22.1 | 15 | 13 | 16 | 12 | 14.0 | 3.08 |
| Example 2 | | | | | | | | | |

In each of Examples 1 to 6 and Comparative Examples 1 and 2, an aluminum thin film with a thickness of 900 nm was formed by using the corresponding aluminum sputtering target, and Mo thin films, each having a thickness of 70 nm, were laminated as upper and lower layers on the aluminum thin film, followed by a heat treatment at 450° C. for one hour. Finally, the resistivity of the obtained aluminum thin film was measured. The measurement results are shown in Table 1.

With regard to the number of film-formed substrates until the number of splashes becomes one or less, when Examples 1 to 3 were compared with Comparative Example 1, in which cutting was conducted as the surface finishing method, the average value of the numbers of film-deposited substrates in each of Examples 1 to 3 was obviously small, specifically, in a range of 11.0 to 15.8, compared to Comparative Example 1 in which the average number thereof was 22.8. Likewise, with regard to the number of film-formed substrates until the number of splashes becomes one or less, when Examples 4 to 6 were compared with Comparative Example 2 in which polishing was conducted as the surface finishing method, the average value of the numbers of film-deposited substrates in each of Examples 4 to 6 was obviously small, specifically, in a range of 7.3 to 10.0, compared to Comparative Example 2 in which the average number thereof was 14.0. From these results, it is found that in each of Examples using either cutting or polishing as the surface finishing, the occurrence of flaws on the surface of the sample was reduced, compared to the samples in Comparative Examples.

With regard to the Vickers hardness, the sample in each of Examples had a Vickers hardness of 25 or more, whereas the sample in each of Comparative Examples had a Vickers hardness of less than 25. In all samples, the thin-film resistivity was within a narrow range of 3.00 to 3.12 μΩcm, which means that these resistivities in all samples were equivalent.

1. An aluminum sputtering target, comprising:
0.005 atomic % to 0.04 atomic % of Ni;
0.005 atomic % to 0.06 atomic % of La; and
Al.

2. The aluminum sputtering target according to claim 1, wherein a Vickers hardness is 25 or more.

3. The aluminum sputtering target according to claim 1, comprising:
0.01 atomic % to 0.03 atomic % of Ni; and
0.03 atomic % to 0.05 atomic % of La.

4. The aluminum sputtering target according to claim 2, comprising:
0.01 atomic % to 0.03 atomic % of Ni; and
0.03 atomic % to 0.05 atomic % of La.
